(19) United States
(12) Patent Application Publication
(10) Pub. No.: US 2024/0179992 A1
(43) Pub. Date: May 30, 2024

(54) DISPLAY DEVICE

(71) Applicant: LG Display Co., Ltd., Seoul (KR)

(72) Inventor: Joonsuk LEE, Paju-si (KR)

(21) Appl. No.: 18/342,628

(22) Filed: Jun. 27, 2023

(30) Foreign Application Priority Data
Nov. 30, 2022 (KR) 10-2022-0164115

(51) Int. Cl. H10K 59/38; H10K 59/80

(52) U.S. Cl. CPC H10K 59/38; H10K 59/873; H10K 59/8792

(57) ABSTRACT

Disclosed is a display device comprising a circuit portion including a first substrate with a plurality of subpixels and a light emitting element positioned on an upper surface of the first substrate, a color filter portion including a second substrate and a plurality of color filters positioned on a lower surface of the second substrate, and an encapsulation portion which bonds the circuit portion and the color filter portion to each other, wherein a plurality of concave portions and a flat portion surrounding each of the plurality of concave portions are positioned on the lower surface of the second substrate, and the plurality of color filters are positioned in the plurality of concave portions.

### BACKGROUND

### Technical Field

The present disclosure relates to a display device.

### Description of the Related Art

According to a development of information society, a demand for a display device for displaying an image is increased in various forms. Thus, various display devices such as a liquid crystal display device LCD, a plasma display panel device PDP, and an electroluminescence display device ELD, etc., have been used recently. The electroluminescent display device may include a display device such as an organic light emitting display device OLED and a quantum dot light emitting display device QLED, etc.

Among the display devices, the electroluminescent display device is a self-luminous display device. The electroluminescent display device has excellent viewing angle and high contrast ratio, and the like, compared to the liquid crystal display device LCD. Also, the electroluminescent display device does not require a separate backlight, whereby it has advantages of lightweight thin profile and low power consumption. In addition, the electroluminescent display device may be driven at a DC low voltage, may have a rapid response speed, and may have an advantage of low manufacturing cost.

The description provided in the background section should not be assumed to be prior art merely because it is mentioned in or associated with the background section. The background section may include information that describes one or more aspects of the subject technology.

### BRIEF SUMMARY

Additional features and aspects will be set forth in part in the following description and in part will become apparent from the following description, or may be learned by practice of the inventive concepts provided herein. Other features and aspects of the inventive concepts may be realized and attained by the structure particularly pointed out, or derivable therefrom, in the written description, the claims hereof, and the appended drawings

In a related art, top emission method may use a structure in which a lower substrate on which a driving circuit and a light emitting element are formed is bonded to an upper substrate on which a color filter is formed. In this case, light generated from the light emitting element or light reflected from the inside of the display device may be emitted to an adjacent subpixel rather than a corresponding subpixel by a distance between the lower substrate and the upper substrate.

In this case, since a light leakage occurs in the display device, the light emitted to the adjacent subpixel may be absorbed by a black matrix formed between adjacent color filters. However, as a distance between the lower substrate and the upper substrate increases, it necessarily requires the increase of width in the black matrix, thereby reducing an aperture ratio. Alternatively, in order to maintain the width of the black matrix even when the distance between the lower substrate and the upper substrate increases, a thickness of the black matrix may be increased. However, as the thickness of the black matrix increases, the color filter is not stably deposited, whereby the thickness of the color filter may not be uniform. Accordingly, an image quality in each subpixel may be degraded due to non-uniformity in thickness of the color filter.

The present disclosure has been made in view of the above problems, and it is an object of the present disclosure to provide a display device capable of displaying a high-definition image by the improvement of color uniformity and enabling a low-power driving by the increase of aperture ratio.

In accordance with an aspect of the present disclosure, the above and other objects may be accomplished by the provision of a display device comprising a circuit portion including a first substrate with a plurality of subpixels and a light emitting element formed on an upper surface of the first substrate, a color filter portion including a second substrate and a plurality of color filters formed on a lower surface of the second substrate, and an encapsulation portion which bonds the circuit portion and the color filter portion to each other, wherein a plurality of concave portions and a flat portion surrounding each of the plurality of concave portions are formed on the lower surface of the second substrate, and the plurality of color filters are formed in the plurality of concave portions.

In addition to the effects of the present disclosure as mentioned above, additional advantages and features of the present disclosure will be clearly understood by those skilled in the art from the above description of the present disclosure.

It is to be understood that both the foregoing general description and the following detailed description are exemplary and explanatory and are intended to provide further explanation of the inventive concepts as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the description serve to explain the principle of the disclosure. The above and other objects, features and other advantages of the present disclosure will be more clearly understood from the following detailed description taken in conjunction with the accompanying drawings, in which:

FIG. 1 is a cross sectional view illustrating a display device according to the first embodiment of the present disclosure;

FIG. 2 is a cross sectional view illustrating a display device according to the second embodiment of the present disclosure;

FIG. 3 is a cross sectional view illustrating a display device according to the third embodiment of the present disclosure; and

FIG. 4 is a cross sectional view illustrating a display device according to the fourth embodiment of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. In the following description, when a detailed description of well-known functions or configurations related to this document is determined to unnecessarily cloud a gist of the inventive concept, the detailed description thereof will be omitted. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. In the case in which “comprise.” “have,” and “include” described in the present specification are used, another part may also be present unless “only” is used. The terms in a singular form may include plural forms unless noted to the contrary.

When terms “comprise.” “have.” and “include” described in the present disclosure may be used, another part may be added unless a more limiting terms, such as “only.” is used. The terms of a singular form may include plural forms unless referred to the contrary.

Any implementation described herein as an “example” is not necessarily to be construed as preferred or advantageous over other implementations.

In construing an element, the element is construed as including an error region although there is no explicit description thereof.

In describing a positional relationship, for example, when the positional order is described as “on,” “above.” “below.” “beneath,” and “next.” the case of no contact therebetween may be included, unless “just” or “direct” is used. For example, where an element or layer is disposed “on” another element or layer, a third layer or element may be interposed therebetween.

The terms, such as “below,” “lower,” “above.” “upper” and the like, may be used herein to describe a relationship between element item(s) as illustrated in the drawings. It will be understood that the terms are spatially relative and based on the orientation depicted in the drawings.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” encompasses the combination of all three listed elements, combinations of any two of the three elements, as well as each individual element, the first element, the second element, and the third element.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in a co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

It will be apparent to those skilled in the art that various modifications and variations can be made in the present disclosure without departing from the technical idea or scope of the disclosures. Thus, it may be intended that embodiments of the present disclosure cover the modifications and variations of the disclosure provided they come within the scope of the appended claims and their equivalents.

Hereinafter, a display device according to the present disclosure will be described with reference to the accompanying drawings.

### First Embodiment

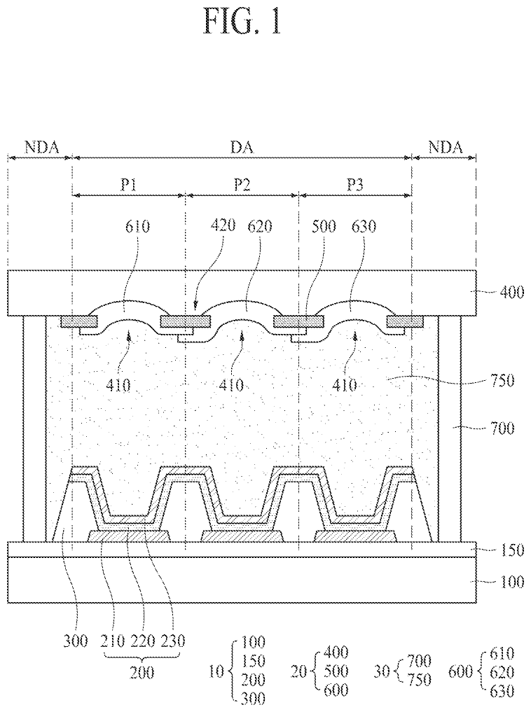

FIG. 1 is a cross sectional view illustrating a display device according to the first embodiment of the present disclosure.

Referring to FIG. 1, the display device according to the first embodiment of the present disclosure discloses a structure in which a circuit portion 10 and a color filter portion 20 disposed on the circuit portion 10 are bonded to each other, for example, by an encapsulation portion 30.

The circuit portion 10 may include a first substrate 100, a circuit element layer 150, a light emitting element 200, and a bank 300.

The first substrate 100 may be formed of glass, metal foil or plastic, but not limited thereto. The display device according to the first embodiment of the present disclosure may be configured by a top emission method in which light is emitted toward an upper portion. Therefore, the first substrate 100 may be made of an opaque material as well as, a semitransparent material and/or a transparent material.

A display area DA for emitting light and a non-display area NDA adjacent to or surrounding the display area DA may be formed on the first substrate 100. In addition, first to third subpixels P1 to P3 may be formed in the display area DA. The first subpixel P1 may emit red light R, the second subpixel P2 may emit green light G, and the third subpixel P3 may emit blue light B, but not limited thereto. As an example, a subpixel emitting white light may be further included. As an example, at least one of the subpixels P1 to P3 may emit white light or light of other colors such as cyan, magenta, yellow, etc. That is, an arrangement order of each of the first to third subpixels P1 to P3 may be variously changed.

The circuit element layer 150 may be formed on the first substrate 100. In the circuit element layer 150, a circuit element including various signal lines, a thin film transistor, and a capacitor may be formed in each of the first to third subpixels P1 to P3. The signal lines may include a gate line, a data line, a power line, and/or a reference line, etc. The thin film transistor may include a switching thin film transistor, a driving thin film transistor, and/or a sensing thin film transistor, etc.

The switching thin film transistor may be switched according to a gate signal supplied to the gate line and may be configured to supply a data voltage supplied from the data line to the driving thin film transistor. The driving thin film transistor may be switched according to a data voltage supplied from the switching thin film transistor and may be configured to generate a data current from a power source supplied from the power line and to supply the data current to a first electrode 210. The sensing thin film transistor may sense a threshold voltage of the driving thin film transistor and/or a threshold voltage deviation of the driving thin film transistor which causes deterioration of image quality, and may supply the current of the driving thin film transistor to the reference line in response to a sensing control signal, for example, supplied from the gate line or a separate sensing line.

The capacitor may maintain the data voltage supplied to the driving thin film transistor for one frame, and may be connected to a gate terminal and a source terminal of the driving thin film transistor, respectively.

The light emitting element 200 may be formed on the circuit element layer 150. The light emitting element 200 may include the first electrode 210, a light emitting layer 220, and a second electrode 230.

The first electrode 210 may be formed on the circuit element layer 150. The first electrode 210 is formed in each of the first to third subpixels P1 to P3, wherein the first electrode 210 may function as an anode of the light emitting element. The first electrode 210 may be electrically connected to the driving thin film transistor formed in the circuit element layer 150.

The first electrode 210 may include a conductive material, e.g., a transparent conductive material. For example, the first electrode 210 may include a transparent conductive material such as Indium Tin Oxide ITO or Indium Zinc Oxide IZO, etc. Alternatively, the first electrode 210 may include a metal material such as aluminum Al, silver Ag, copper Cu, molybdenum Mo, titanium Ti, tungsten W, or chrome Cr, etc., or an alloy thereof. Also, the first electrode 210 is illustrated as a single layer, but may be formed as multiple layers. For example, the first electrode 210 may be formed as a triple layer in which a transparent conductive material, a metal material, and a transparent conductive material are sequentially stacked, without being limited thereto.

The bank 300 is formed in the boundary between each of the first to third subpixels P1 to P3, to thereby define a light emitting area in each of the first to third subpixels P1 to P3. That is, an opening area in which the bank 300 is not formed in each of the first to third subpixels P1 to P3 may be the light emitting area. Also, the bank 300 may be formed to cover or not cover at least one end of the first electrode 210.

The bank 300 may include an insulating material. As an example, the bank 300 may include an organic insulating material such as acryl resin, epoxy resin, phenolic resin, polyamide resin, and/or polyimide resin, etc. Alternatively, the bank 300 may include an inorganic insulating material such as silicon nitride, aluminum nitride, zirconium nitride, titanium nitride, hafnium nitride, tantalum nitride, silicon oxide, aluminum oxide, or titanium oxide, etc. In addition, the bank 300 may be formed to include a black dye, for example, to absorb light incident or reflected from the inside or outside.

The light emitting layer 220 may be formed on the first electrode 210. As an example, the light emitting layer 220 may be also formed on at least a part of the bank 300. As an example, the light emitting layer 220 may be continuously formed in the first to third subpixels P1 to P3 and the boundary therebetween.

The light emitting layer 220 emits white light and may include an organic light emitting layer. As an example, the light emitting layer 220 may further include at least one of a hole transport layer, a hole injection layer, an hole blocking layer, an electron transport layer, an electron injection layer, and an electron blocking layer. In this case, when a voltage is applied to the first electrode 210 and the second electrode 230, holes and electrons move to the organic light emitting layer (e.g., through the hole transport layer and the electron transport layer, respectively), and may be combined in the organic light emitting layer to emit light.

The second electrode 230 may be formed on the light emitting layer 220. The second electrode 230 may function as a cathode of the light emitting element. In the same manner as the light emitting layer 220, the second electrode 230 may be formed in the first to third subpixels P1 to P3 and/or the boundary therebetween. As an example, the second electrode 230 may also be formed on the first electrode 210 and the bank 300.

As the display device according to the first embodiment of the present disclosure is formed in a top emission method, the second electrode 230 includes a semitransparent conductive material or a transparent conductive material such as Indium Tin Oxide ITO or Indium Zinc Oxide IZO, etc., to transmit the light emitted from the light emitting layer 220 to an upper portion. The second electrode 230 may be formed of a single layer or multiple layers.

The color filter portion 20 may include a second substrate 400, a black matrix 500, and a color filter 600.

The second substrate 400 may include a plurality of concave portions 410 and a plurality of flat portion 420.

The plurality of concave portions 410 are formed overlapping (e.g., inside) the first to third subpixels P1 to P3 and are spaced apart from each other. As an example, the plurality of concave portions 410 may be formed overlapping the first to third subpixels P1 to P3 in a one to one correspondence. As an example, each of the plurality of concave portions 410 may have a size equal to or greater than a size of the light emitting area of the corresponding subpixel. As an example, each of the plurality of concave portions 410 may overlap the entirety of the light emitting area of the corresponding subpixel. The plurality of concave portions 410 may be formed by etching a lower portion of the second substrate 400 to a predetermined depth. Referring to FIG. 1, an inner surface in each of the plurality of concave portions 410 may have a round shape, a curved shape, an oval shape, etc., but not limited thereto. Also, referring to FIG. 1, each of the plurality of concave portions 410 may gradually increase in depth from both ends to the center, but not limited thereto. For example, both side surfaces and the lower surface of the plurality of concave portions 410 may be flat, and a region in which each side surface and the lower surface are connected may have a round shape.

The flat portion 420 is a region adjacent to or surrounding the plurality of concave portions 410, and the flat portion 420 may be formed to be flat. As an example, the flat portion 420 may be a region between the adjacent concave portions 410 or between the concave portions 410 and the non-display area NDA and may be formed in the boundary region of the first to third subpixels P1 to P3. A width of the flat portion 420 between the concave portions 410 adjacent to each other may be 1 μm or more. As an example, the flat portion 420 may overlap the corresponding bank 300.

The second substrate 400 may be formed of a transparent material such as glass or plastic, but not limited thereto. The display device according to the first embodiment of the present disclosure may be configured in a top emission method in which light is emitted toward an upper portion. Therefore, since the light emitted from the light emitting element 200 needs to be transmitted, the second substrate 400 may be made of a transparent material.

The black matrix 500 may be formed under the second substrate 400. The black matrix 500 is formed as a matrix configuration in the boundary between the first to third subpixels P1 to P3, to thereby prevent light leakage in the boundary between the first to third subpixels P1 to P3. Also, an upper surface of the black matrix 500 may be flat and, for example, may be formed to be in contact with the flat portion 420, without being limited thereto. Referring to FIG. 1, a width of the black matrix 500 may be greater than the width of the flat portion 420 between the concave portions 410 formed in the boundary between the first to third subpixels P1 to P3. As an example, a portion of the black matrix 500 may overlap the concave portion 410. In this case, the upper surface of the black matrix 500 may be formed to be spaced apart from the concave portion 410 without being bent along the concave portion 410.

Alternatively, although not shown in the drawings, the width of the black matrix 500 may be less than or equal to the width of the flat portion 420 between the concave portions 410 formed in the boundary between the first to third subpixels P1 to P3, so that the black matrix 500 may not overlap the concave portion 410. In addition, when the thickness of the black matrix 500 is 0.8 μm or more and 1.5 μm or less, a distance from the deepest inner surface of the concave portion 410 to the lower surface of the black matrix 500 may be 3.2 μm or more and 6.2 μm or less, but not limited thereto.

The color filter 600 may be formed under the second substrate 400. The color filter 600 may include first to third color filters 610 to 630. The first color filter 610 is formed in the first subpixel P1 and is configured to transmit red light R, the second color filter 620 is formed in the second subpixel P2 and is configured to transmit green light G, and the third color filter 630 is formed in the third subpixel P3 and is configured to transmit blue light B, but not limited thereto.

Each of the first to third color filters 610 to 630 may be formed along the shape of the inner surface of the concave portion 410. Specifically, referring to FIG. 1, when the inner surface of the concave portion 410 has a round shape, a lower surface of each of the first to third color filters 610 to 630 may have a concavely rounded shape. As an example, the lower surface of each of the first to third color filters 610 to 630 may be bent. Also, each of the first to third color filters 610 to 630 may be formed to have a uniform thickness inside the concave portion 410, without being limited thereto.

Referring to FIG. 1, each of first to third color filters 610 to 630 may be formed to fill a region between the black matrix 500 and the concave portion 410. That is, when the width of the black matrix 500 is greater than the width of the flat portion 420 formed in the boundary between the first to third subpixels P1 to P3, a portion of the upper surface of the black matrix 500 may be exposed by the flat portion 420. Each of the first to third color filters 610 to 630 may be formed to cover a portion of the upper surface of the black matrix 500, and more particularly, a portion adjacent to or overlapping the concave portion 410.

Each of the first to third color filters 610 to 630 extends from the concave portion 410 and may to be formed in the flat portion 420. Referring to FIG. 1, each of the first to third color filters 610 to 630 may be formed to cover a portion of the black matrix 500. That is, the first to third color filters 610 to 630 may cover the side surface or upper surface of the black matrix 500, but not limited thereto. Also, the color filters 600 adjacent to each other may be in contact with each other on the lower surface of the black matrix 500, but not limited thereto. In addition, the thickness of the first to third color filters 610 to 630 formed on the inner surface of the concave portion 410 may be greater than the thickness of the black matrix 500.

In the first embodiment of the present disclosure, the plurality of concave portions 410 and the flat portions 420 are formed on the second substrate 400, to thereby form the step difference on the lower portion of the second substrate 400. The color filter 600 may be formed on the lower surface of the plurality of concave portions 410, and the black matrix 500 may be formed on the lower surface of the flat portion 420. Accordingly, the step difference between the color filter 600 and the black matrix 500 may be increased, as compared to a structure in which the entire lower surface of the second substrate 400 is formed as a flat surface. Therefore, even if the thickness of the black matrix 500 is not increased, it may have the same effect as increasing the thickness of the black matrix 500 through the step difference of the second substrate 400. That is, the light blocking efficiency of the black matrix 500 is increased while maintaining the thickness of the black matrix 500.

In the structure in which the entire lower surface of the second substrate 400 is formed as a flat surface, when only the thickness of the black matrix 500 is increased, the step difference between the lower surface of the second substrate 400 and the black matrix 500 increases, so that the end of the color filter 600 being in contact with the black matrix 500 may be thicker than the center of the color filter 600. However, according to the first embodiment of the present disclosure, the color filter 600 is formed inside the concave portion 410 of the second substrate 400 without increasing the thickness of the black matrix 500. Accordingly, the color filter 600 may be uniformly formed along the rounded inner surface of the concave portion 410. Thus, since the thickness of the color filter 600 is uniformly formed, stains of the display device may be reduced. The encapsulation portion 30 may include a dam 700 and an encapsulation layer 750.

The dam 700 is formed in the non-display area NDA and may be formed between the circuit portion 10 and the color filter portion 20. As an example, the dam 700 may adhere the circuit portion 10 and the color filter portion 20 to each other, and fixes the circuit portion 10 and the color filter portion 20 to be spaced apart from each other by a predetermined distance. In addition, the dam 700 is formed to at least partially surround the display area DA, thereby reducing or preventing external moisture from being introduced into the display area DA. The dam 700 may be formed of an inorganic insulating material such as silicon oxide SiOx or silicon nitride SiNx, etc., or an organic insulating material.

The encapsulation layer 750 is formed to fill a space surrounded by the dam 700, to thereby reduce or prevent external moisture from penetrating the light emitting device 200. The encapsulation layer 750 may include an inorganic insulating material such as silicon oxide SiOx or silicon nitride SiNx, etc. Alternatively, the encapsulation layer 750 may include an organic insulating material such as acryl resin, epoxy resin, phenolic resin, polyamide resin, or polyimide resin, etc.

Although not shown in the drawings, an absorbing film may be optionally formed on the upper surface of the second substrate 400. The absorbing film may be formed on the entire surface of the first to third subpixels P1 to P3. Accordingly, it is possible to minimize luminance reduction while reducing or preventing external light from being introduced.

### Second Embodiment

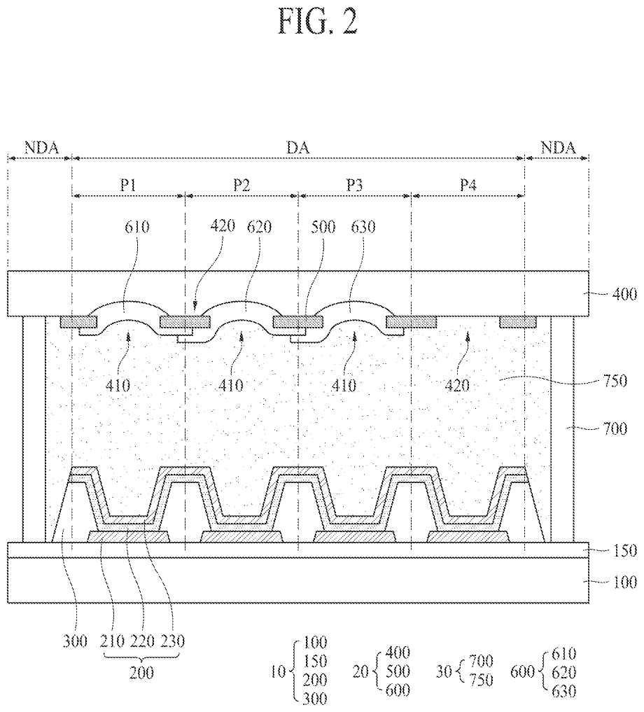

FIG. 2 is a cross sectional view illustrating a display device according to the second embodiment of the present disclosure. Herein, elements identical to those of the display device shown in FIG. 1 are denoted by the same reference numerals, and repeated descriptions thereof are omitted or briefly given.

As described above, a circuit portion 10 may include a first substrate 100, a circuit element layer 150, a light emitting element 200, and a bank 300.

The display device according to FIG. 2 may further include a fourth subpixel P4. As described above, a first subpixel P1 may emit red light R, a second subpixel P2 may emit green light G, and a third subpixel P3 may emit blue light B, but not limited thereto. That is, an arrangement order of each of the first to third subpixels P1 to P3 may be variously changed. In this case, the fourth subpixel P4 may emit white light W.

The fourth subpixel P4 may include the same elements as those such as the circuit element layer 150, the light emitting element 200, and the bank 300 formed in each of the first to third subpixels P1 to P3.

As described above, a color filter portion 20 may include a second substrate 400, a black matrix 500, and a color filter 600.

One concave portion 410 and one of the first to third color filters 610 to 630 may be formed in each of the first to third subpixels P1 to P3. On the other hand, the concave portion 410 and the color filter 600 may be omitted from the fourth subpixel P4.

Since the fourth subpixel P4 emits white light W generated by the light emitting element 200 as it is, the color filter 600 may not be formed in the fourth subpixel P4. In this case, since the concave portion 410 increases the step difference between the color filter 600 and the black matrix 500, the concave portion 410 may not be formed in the fourth subpixel P4 from which the color filter 600 is omitted. That is, a flat portion 420 formed in the boundary between the third subpixel P3 and the fourth subpixel P4 may extend to an inner region of the fourth subpixel P4. Accordingly, even when the fourth subpixel P4 is additionally formed, a process of etching the second substrate 400 may not be increased.

### Third Embodiment

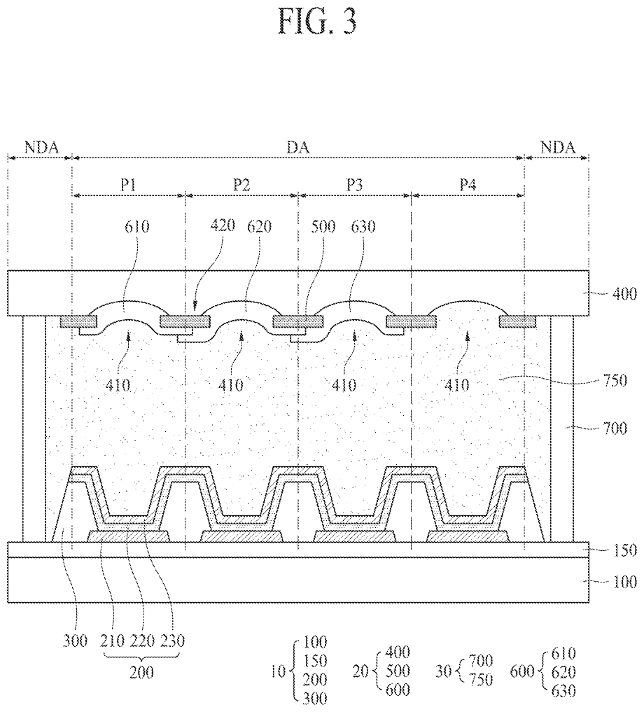

FIG. 3 is a cross sectional view illustrating a display device according to the third embodiment of the present disclosure.

The display device according to FIG. 3 has the substantially same structure as the display device of FIG. 2 except for a structure of a fourth subpixel P4. Therefore, the same reference numerals are used for the same elements as those of the display device shown in FIG. 2, and repeated descriptions are omitted or briefly given.

Referring to FIG. 3, in comparison with the second embodiment, the third embodiment discloses that a concave portion 410 is additionally formed in a fourth subpixel P4. The concave portion 410 formed in the fourth subpixel P4 may be formed in the same shape as a concave portion 410 formed in each of first to third subpixels P1 to P3. But embodiments are not limited thereto. For example, the concave portion 410 formed in the fourth subpixel P4 may be formed in a shape or size different from those of the concave portion 410 formed in each of first to third subpixels P1 to P3.

Since the fourth subpixel P4 emits white light generated by a light emitting device 200 as it is, a color filter 600 may not be formed in the fourth subpixel P4. Accordingly, the inside of the concave portion 410 formed in the fourth subpixel P4 may be filled with an encapsulation layer 750. Thus, mobility of the encapsulation layer 750 is reduced, whereby a distance between a circuit portion 10 and a color filter portion 20 may be maintained more stably.

### Fourth Embodiment

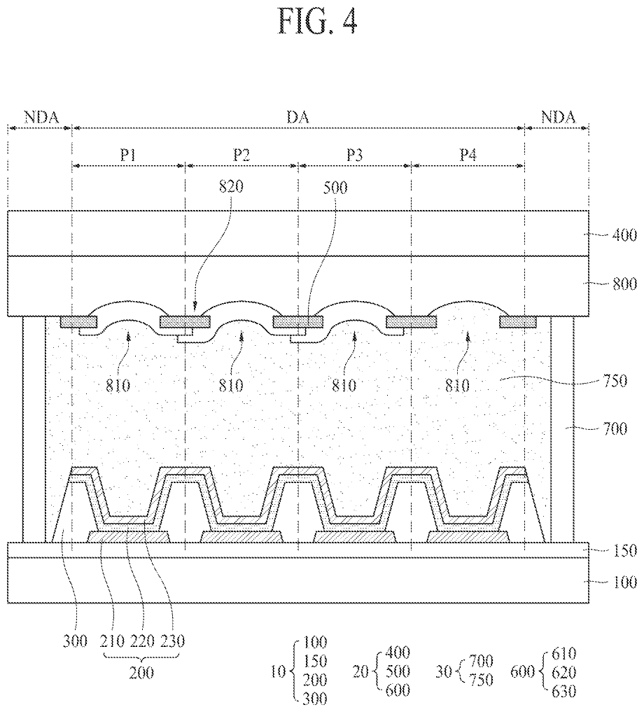

FIG. 4 is a cross sectional view illustrating a display device according to the fourth embodiment of the present disclosure.

The display device according to FIG. 4 has the substantially same structure as the display device of FIG. 3 except for a structure of a color filter portion 20. Therefore, the same reference numerals are used for the same elements as those of the display device shown in FIG. 3, and repeated descriptions are omitted or briefly given.

Referring to FIG. 4, in comparison with the third embodiment, the fourth embodiment further discloses that a planarization layer 800 is additionally formed in the color filter portion 20. That is, the color filter portion 20 may include a second substrate 400, a black matrix 500, a color filter 600, and the planarization layer 800.

A lower surface of the second substrate 400 is formed to be flat, and the planarization layer 800 may be formed on a lower portion of the second substrate 400.

The planarization layer 800 may include a plurality of concave portions 810 and a plurality of flat portions 820.

The plurality of concave portions 810 may be formed in the inside of each of first to fourth subpixels P1 to P4 and may be spaced apart from each other. The plurality of concave portions 810 may be formed by etching a lower portion of the planarization layer 800 to a predetermined depth. Referring to FIG. 4, an inner surface of each of the plurality of concave portions 810 may have a round shape, a curved shape, an oval shape, etc., but not limited thereto. Also, referring to FIG. 4, each of the plurality of concave portions 810 may gradually increase in depth from both ends to the center, but not limited thereto. For example, both side surfaces and the lower surface of the plurality of concave portions 810 may be flat, and a region in which each side surface and the lower surface are connected may have a round shape.

The flat portion 820 is a region adjacent to or surrounding the plurality of concave portions 810 and, for example, may be formed to be flat. The flat portion 820 may be a region between the adjacent concave portions 810 or between the concave portions 810 and the non-display area NDA and may be formed in the boundary of the first to fourth subpixels P1 to P4. A width of the flat portion 820 between the concave portions 810 adjacent to each other may be 1 μm or more.

The black matrix 500 may be formed under the planarization layer 800. As described above, the black matrix 500 may be formed as a matrix configuration in the boundary between the first to fourth subpixels P1 to P4, to thereby prevent light leakage in the boundary between the first to fourth subpixels P1 to P4. At this time, an upper surface of the black matrix 500 may be formed to be spaced apart from the concave part 810 without being bent along the concave portion 810.

The color filter 600 may be formed under the planarization layer 800. The color filter 600 may include the first to third color filters 610 to 630. As described above, each of the first to third color filters 610 to 630 may be formed along the shape of the inner surface of the concave portion 810.

Referring to FIG. 4, in the same manner as the third embodiment, the fourth embodiment discloses that the inside of the concave portion 810 formed in the fourth subpixel P4 is filled with an encapsulation layer 750. Therefore, mobility of the encapsulation layer 750 is reduced, whereby a distance between a circuit portion 10 and the color filter portion 20 may be maintained more stably.

Referring to FIG. 4, in comparison with the third embodiment, the fourth embodiment additionally forms the planarization layer 800 between the second substrate 400 and the color filter 600, thereby reducing the distance between the circuit portion 10 and the color filter portion 20. Accordingly, the circuit portion 10 and the color filter portion 20 may be more stably attached. In addition, it is possible to reduce a possibility of emitting light from a light emitting element 200 to the adjacent subpixel other than the corresponding subpixel.

According to the present disclosure, the color filter is arranged inside the concave portion of the substrate or the planarization layer so that it is possible to realize the high-definition image by the improvement of color uniformity and to enable the low-power driving of the display device by the increase of aperture ratio.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a circuit portion including a first substrate with a plurality of subpixels and a light emitting element formed on an upper surface of the first substrate;
a color filter portion including a second substrate and a plurality of color filters formed on a lower surface of the second substrate;
an encapsulation portion between the circuit portion and the color filter portion; and
a plurality of concave portions and a flat portion surrounding each of the plurality of concave portions are positioned on the lower surface of the second substrate,
wherein the plurality of color filters are positioned in the plurality of concave portions, respectively.

2. The display device according to claim 1,
wherein each of the plurality of concave portions overlaps a corresponding one of the plurality of subpixels.

3. The display device according to claim 1,
wherein each of the plurality of concave portions is positioned inside a corresponding one of the plurality of subpixels.

4. The display device according to claim 1,
wherein the color filter portion further includes a black matrix positioned in the boundary of the plurality of subpixels, and
the black matrix is positioned on a lower surface of the flat portion.

5. The display device according to claim 4,
wherein a width of the black matrix is greater than a width of the flat portion, such that a portion of the black matrix overlap at least one of the plurality of concave portions.

6. The display device according to claim 5,
wherein an upper surface of the portion of the black matrix is spaced apart from the at least one concave portion.

7. The display device according to claim 6,
wherein a color filter of the plurality of color filters positioned in the at least one concave portion fills a space between the portion of the black matrix and the at least one concave portion.

8. The display device according to claim 5,
wherein a color filter of the plurality of color filters positioned in the at least one concave portion contacts a side surface and a lower surface of the black matrix as well as an upper surface of the portion of the black matrix.

9. The display device according to claim 4,
wherein a thickness of the plurality of color filters is greater than a thickness of the black matrix.

10. The display device according to claim 9,
wherein at least two color filters adjacent to each other is in contact with each other on the lower surface of the black matrix.

11. The display device according to claim 1,
wherein the plurality of subpixels include at least one subpixel which does not include the color filter.

12. The display device according to claim 11,
wherein the flat portion extends to at least one subpixel.

13. The display device according to claim 11,
wherein a concave portion of the plurality of concave portions corresponding to the at least one subpixel is filled with the encapsulation layer.

14. The display device according to claim 1,
wherein the encapsulation portion bonds the circuit portion and the color filter portion to each other.

15. The display device according to claim 1,
wherein the plurality of subpixels include first to third subpixels, and
the plurality of color filters include first to third color filters respectively positioned in the first to third subpixels.

16. The display device according to claim 14,
wherein the plurality of concave portions are positioned in the respective first to third subpixels and are provided to be spaced apart from each other, and
the flat portion is positioned in the boundary of the first to third subpixels.

17. The display device according to claim 16,
wherein the plurality of subpixels further include a fourth subpixel adjacent to the third subpixel, and
the fourth subpixel emits white light and does not include the color filter.

18. The display device according to claim 17, wherein the flat portion extends to the fourth subpixel.

19. The display device according to claim 17,
wherein a concave portion is further positioned in the fourth subpixel, and
the flat portion is positioned in the boundary of the first to fourth subpixels.

20. The display device according to claim 1,
wherein an inner surface of each of the plurality of concave portions has a curved shape, and
the color filter is positioned to be bent along the inner surface of each of the plurality of concave portions inside the plurality of concave portions.

21. The display device according to claim 1,
wherein a thickness of the color filter is uniform inside the plurality of concave portions.

22. The display device according to claim 15,
wherein the color filter portion further includes a black matrix positioned in the boundary of the first to third subpixels, and
the black matrix is positioned on a lower surface of the flat portion.

23. The display device according to claim 22,
wherein an upper surface of the black matrix is flat and is spaced apart from the concave portion.

24. The display device according to claim 22,
wherein the color filter extends from the concave portion and covers a portion of the upper surface of the black matrix.

25. A display device comprising:
a circuit portion including a first substrate with a plurality of subpixels and a light emitting element positioned on an upper surface of the first substrate;
a color filter portion including a second substrate, and a planarization layer and a plurality of color filters positioned on a lower surface of the second substrate; and
an encapsulation portion between the circuit portion and the color filter portion,
wherein a plurality of concave portions and a flat portion surrounding each of the plurality of concave portions are positioned on a lower surface of the planarization layer, and
the plurality of color filters are positioned inside the plurality of concave portions, respectively.
